(19) United States
(12) Patent Application Publication
(10) Pub. No.: US 2025/0212429 A1
(43) Pub. Date: Jun. 26, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shunsuke ASABA, Himeji Hyogo (JP); Hiroshi KONO, Himeji Hyogo (JP)

(21) Appl. No.: 19/076,949

(22) Filed: Mar. 11, 2025

Related U.S. Application Data
(63) Continuation of application No. PCT/JP2024/005345, filed on Feb. 15, 2024.

(30) Foreign Application Priority Data
Jul. 18, 2023 (JP) 2023-116913

(51) Int. Cl. H10D 8/60; H10D 64/62; H10D 64/64

(52) U.S. Cl. CPC H10D 8/60; H10D 64/62; H10D 64/64

(57) ABSTRACT

According to one embodiment, a semiconductor device includes a first electrode, a second electrode, a third electrode, a first semiconductor member, a second semiconductor member, a third semiconductor member, a fourth semiconductor member, and a first insulating member. The first semiconductor member is provided between the first and second electrodes, and is of a first conductivity type. The first semiconductor member includes a first partial region, a second partial region, a third partial region, a fourth partial region, and a fifth partial region. The second semiconductor member is of a second conductivity type. The second semiconductor member includes a first semiconductor region, a second semiconductor region, a third semiconductor region, a fourth semiconductor region, and a fifth semiconductor region. The third semiconductor member is of the second conductivity type. The fourth semiconductor member is of the first conductivity type. The first insulating member includes a first insulating region.

### CROSS-REFERENCE TO RELATED APPLICATIONS

This is a continuation application of International Application PCT/JP2024/005345, filed on Feb. 15, 2024. This application also claims priority to Japanese Patent Application No. 2023-116913, filed on Jul. 18, 2023. The entire contents of which are incorporated herein by reference.

### FIELD

Embodiments described herein generally relate to a semiconductor device.

### BACKGROUND

For example, it is desired to improve the characteristics of semiconductor devices including Schottky barrier diodes and the like.

### BRIEF DESCRIPTION OF THE DRAWINGS

FIG. 1 is a schematic separated cross-sectional view illustrating a semiconductor device according to a first embodiment;

FIG. 2 is a schematic perspective view illustrating the semiconductor device according to the first embodiment;

FIGS. 3A to 3D are schematic cross-sectional views illustrating the semiconductor device according to the first embodiment;

FIG. 4 is a schematic plan view illustrating the semiconductor device according to the first embodiment;

FIGS. 5A to 5D are schematic cross-sectional views illustrating a semiconductor device according to a second embodiment;

FIG. 6 is a schematic cross-sectional view illustrating a semiconductor device according to a third embodiment; and

FIG. 7 is a schematic cross-sectional view illustrating a semiconductor device according to a fourth embodiment.

### DETAILED DESCRIPTION

According to one embodiment, a semiconductor device includes a first electrode, a second electrode, a third electrode, a first semiconductor member, a second semiconductor member, a third semiconductor member, a fourth semiconductor member, and a first insulating member. The first semiconductor member is provided between the first electrode and the second electrode, and is of a first conductivity type. The first semiconductor member includes a first partial region, a second partial region, a third partial region, a fourth partial region, and a fifth partial region. The second partial region and the third partial region are located between a portion of the first partial region and the second electrode in a first direction from the first electrode to the second electrode. A second direction from the second partial region to the third partial region crosses the first direction. The fourth partial region is provided between a portion of the third partial region and the second electrode in the first direction. The fourth partial region is in Schottky contact with the second electrode. The fifth partial region extends along the second direction. The fifth partial region is connected to the second partial region and the third partial region. The second semiconductor member is of a second conductivity type. The second semiconductor member includes a first semiconductor region, a second semiconductor region, a third semiconductor region, a fourth semiconductor region, and a fifth semiconductor region. The first semiconductor region and the second semiconductor region are provided between another portion of the first partial region and the second electrode in the first direction. The first semiconductor region and the second semiconductor region are provided between the second partial region and the third partial region in the second direction. A third direction from the first semiconductor region to the second semiconductor region crosses a plane including the first direction and the second direction. The fifth partial region is provided between the first semiconductor region and the second semiconductor region in the third direction. The third semiconductor region is provided between the first semiconductor region and the second electrode in the first direction. The fourth semiconductor region is provided between the second semiconductor region and the second electrode in the first direction. The fifth semiconductor region is provided between the fifth partial region and the second electrode in the first direction. The third semiconductor member is of the second conductivity type. A portion of the third semiconductor member is provided between the third semiconductor region and the second electrode, and is electrically connected to the second electrode. A third impurity concentration of the second conductivity type in the third semiconductor member is higher than a second impurity concentration of the second conductivity type in the second semiconductor member. The fourth semiconductor member is of the first conductivity type. A portion of the fourth semiconductor member is provided between the third semiconductor region and the second electrode, and is electrically connected to the second electrode. A fourth impurity concentration of the first conductivity type in the fourth semiconductor member is higher than a first impurity concentration of the first conductivity type in the first semiconductor member. A direction from the second partial region to at least a portion of the third electrode is along the first direction. The first insulating member includes a first insulating region. The first insulating region is provided between the second partial region and the at least the portion of the third electrode.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

### First Embodiment

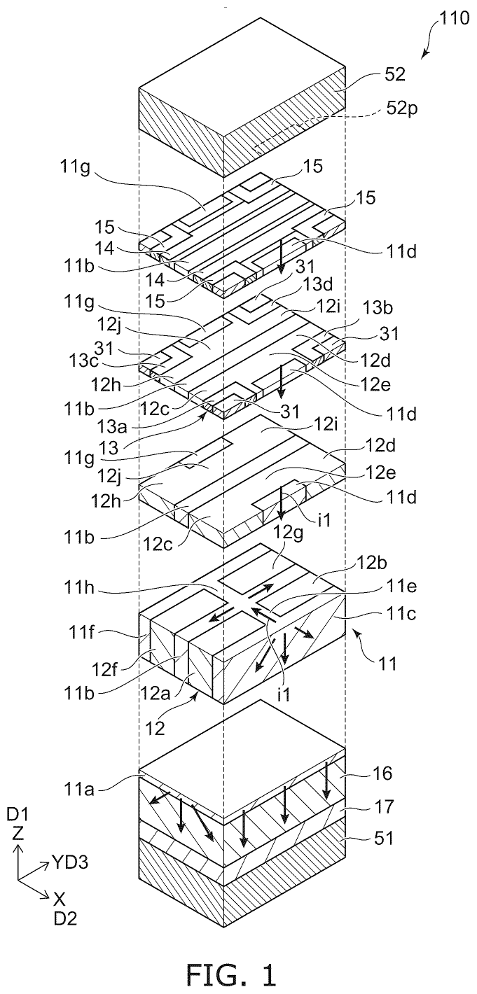

FIG. 1 is a schematic separated cross-sectional view illustrating a semiconductor device according to a first embodiment.

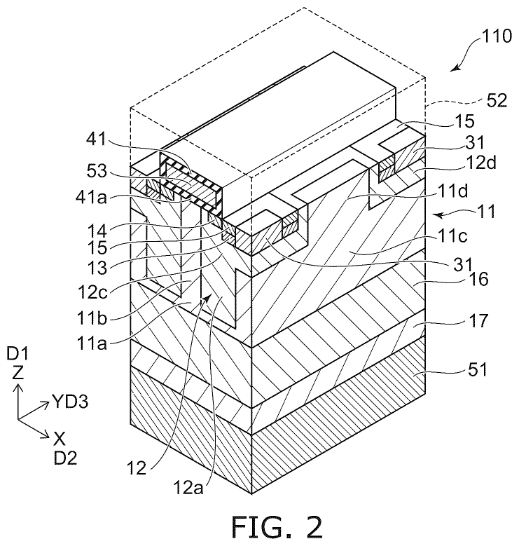

FIG. 2 is a schematic perspective view illustrating the semiconductor device according to the first embodiment.

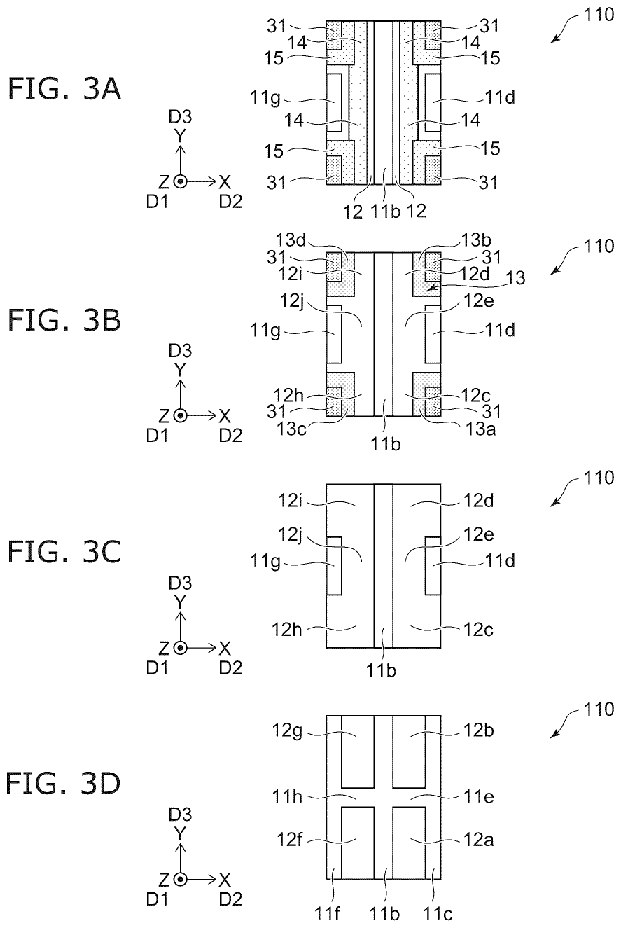

FIGS. 3A to 3D are schematic cross-sectional views illustrating the semiconductor device according to the first embodiment.

As shown in FIGS. 1 and 2, a semiconductor device 110 according to the embodiment includes a first electrode 51, a second electrode 52, a third electrode 53, a first semiconductor member 11, a second semiconductor member 12, a third semiconductor member. 13, a fourth semiconductor member 14, and a first insulating member 41. In FIG. 1, the third electrode 53 and the first insulating member 41 are omitted. In FIG. 1, elements included in semiconductor device 110 are illustrated separated from each other.

A first direction D1 from the first electrode 51 to the second electrode 52 is defined as a Z-axis direction. A direction perpendicular to the Z-axis direction is defined as an X-axis direction. A direction perpendicular to the Z-axis direction and the X-axis direction is defined as a Y-axis direction.

The first semiconductor member 11 is provided between the first electrode 51 and the second electrode 52. The first semiconductor member 11 is of a first conductivity type.

The first semiconductor member 11 includes a first partial region 11a, a second partial region 11b, a third partial region 11c, a fourth partial region 11d, and a fifth partial region 11e. The second partial region 11b and the third partial region 11c are located between a portion of the first partial region 11a and the second electrode 52 in the first direction D1 from the first electrode 51 to the second electrode 52. A second direction D2 from the second partial region 11b to the third partial region 11c crosses the first direction D1. The second direction D2 may be, for example, the X-axis direction.

The fourth partial region 11d is located between a portion of the third partial region 11c and the second electrode 52 in the first direction D1. The fourth partial region 11d makes Schottky contact with the second electrode 52.

The fifth partial region 11e extends along the second direction D2. The fifth partial region 11e is connected to the second partial region 11b and the third partial region 11c. At least a portion of the fifth partial region 11e is located between the second partial region 11b and the third partial region 11c in the second direction D2.

In the first partial region 11a, the second partial region 11b, the third partial region 11c, the fourth partial region 11d, and the fifth partial region 11e, the mutual boundaries may be clear or unclear.

The second semiconductor member 12 is of a second conductivity type. The first conductivity type is one of n-type and p-type. The second conductivity type is the other of n-type and p-type. In the following, it is assumed that the first conductivity type is n-type and the second conductivity type is p-type.

The second semiconductor member 12 includes a first semiconductor region 12a, a second semiconductor region 12b, a third semiconductor region 12c, a fourth semiconductor region 12d, and a fifth semiconductor region 12e. The first semiconductor region 12a and the second semiconductor region 12b are located between another portion of the first partial region 11a and the second electrode 52 in the first direction D1. The first semiconductor region 12a and the second semiconductor region 12b are located between the second partial region 11b and the third partial region 11c in the second direction D2. A third direction D3 from the first semiconductor region 12a to the second semiconductor region 12b crosses a plane including the first direction D1 and the second direction D2. The third direction D3 may be, for example, the Y-axis direction.

The fifth partial region 11e is located between the first semiconductor region 12a and the second semiconductor region 12b in the third direction D3. The first semiconductor region 12a and the second semiconductor region 12b are separated by the fifth partial region 11e.

In the first semiconductor region 12a, the second semiconductor region 12b, the third semiconductor region 12c, the fourth semiconductor region 12d, and the fifth semiconductor region 12e, mutual boundaries may be clear or unclear.

The third semiconductor region 12c is located between the first semiconductor region 12a and the second electrode 52 in the first direction D1. The fourth semiconductor region 12d is located between the second semiconductor region 12b and the second electrode 52 in the first direction D1. The fifth semiconductor region 12e is located between the fifth partial region 11e and the second electrode 52 in the first direction D1.

The third semiconductor member 13 is of the second conductivity type. A portion 13a of the third semiconductor member 13 is located between the third semiconductor region 12c and the second electrode 52. The portion 13a of the third semiconductor member 13 is electrically connected to the second electrode 52. A third impurity concentration of the second conductivity type in the third semiconductor member 13 is higher than a second impurity concentration of the second conductivity type in the second semiconductor member 12. For example, the second semiconductor member 12 is a p region. The third semiconductor member 13 is, for example, a p⁺ region.

The fourth semiconductor member 14 is of the first conductivity type. A portion of the fourth semiconductor member 14 is located between the third semiconductor region 12c and the second electrode 52. The portion of the fourth semiconductor member 14 is electrically connected to the second electrode 52. A fourth impurity concentration of the first conductivity type in the fourth semiconductor member 14 is higher than a first impurity concentration of the first conductivity type in the first semiconductor member 11. For example, the first semiconductor member 11 is an n region. The fourth semiconductor member 14 is an n⁺ region.

A direction from the second partial region 11b to at least a portion of the third electrode 53 is along the first direction D1. The first insulating member 41 includes a first insulating region 41a. The first insulating region 41a is provided between the second partial region 11b and at least a portion of the third electrode 53. The first insulating member 41 electrically insulates between the second partial region 11b and the third electrode 53. A portion of the first insulating member 41 is provided between the fourth semiconductor member 14 and the third electrode 53. The first insulating member 41 electrically insulates between the fourth semiconductor member 14 and the third electrode 53.

A current flowing between the first electrode 51 and the second electrode 52 can be controlled by a potential of the third electrode 53. The potential of the third electrode 53 may be based on a potential of the second electrode 52. The first electrode 51 functions, for example, as a drain electrode. The second electrode 52 functions, for example, as a source electrode. The third electrode 53 functions as, for example, a gate electrode. The semiconductor device 110 is, for example, a transistor.

The second partial region 11b corresponds to, for example, a JFET (Junction Field Effect Transistor) region. The third partial region 11c functions, for example, as a layer for spreading current. The fourth partial region 11d functions as a portion of a Schottky barrier diode (SBD). The region including the fourth semiconductor member 14 functions as a p-n body diode.

In the semiconductor device 110, by providing the SBD including the fourth partial region 11d, a current flows through the SBD, for example, when a reverse voltage is applied. Thereby, it becomes difficult for the p-n body diode to turn on.

In the semiconductor device 110, the fifth partial region 11e is provided. As shown in FIG. 1, when a reverse voltage is applied, a portion of the current i1 flowing through the fourth partial region 11d can flow into the second partial region 11b through the fifth partial region 11e. This suppresses deterioration of the semiconductor device due to hole injection when a reverse voltage is applied. According to the embodiment, reverse conduction characteristics can be improved.

A reference example may be considered in which the fifth partial region 11e is not provided. In the reference example, when a reverse voltage is applied, it is difficult for the current i1 flowing through the fourth partial region 11d to flow toward the second partial region 11b. In the reference example, the reverse conduction property is insufficient.

On the other hand, in the embodiment, by the fifth partial region 11e, a portion of the current i1 flowing through the fourth partial region 11d can flow through the fifth partial region 11e to the second partial region 11b. According to the embodiment, reverse conduction characteristics can be improved. According to the embodiment, a semiconductor device with improved characteristics can be provided.

In the semiconductor device 110, a portion 13a of the third semiconductor member 13 may be in ohmic contact with the second electrode 52, for example.

As shown in FIG. 1, another portion 13b of the third semiconductor member 13 is located between the fourth semiconductor region 12d and the second electrode 52. The other portion 13b of the third semiconductor member 13 may be in ohmic contact with the second electrode 52.

As shown in FIG. 1, the semiconductor device 110 may include a first conductive layer 31. The first conductive layer 31 includes, for example, silicide. At least a portion of the first conductive layer 31 is provided between the third semiconductor member 13 and the second electrode 52. The first conductive layer 31 includes, for example, NiSi. For example, an electrical connection with low electrical resistance is obtained.

As shown in FIG. 1, the second electrode 52 may include a facing region 52p. The facing region 52p faces the fourth partial region 11d. The facing region 52p contains, for example, at least one selected from the group consisting of Ni, Ti, V, and Mo. A Schottky junction is obtained in the portion including the facing region 52p. In the second electrode 52, the entire lower face including the facing region 52p may contain the above-mentioned material.

As shown in FIG. 1, the semiconductor device 110 may further include a fifth semiconductor member 15 of the first conductivity type. A portion of the fifth semiconductor member 15 is provided between the portion 13a of the third semiconductor member 13 and the second electrode 52. The portion of the fifth semiconductor member 15 is electrically connected to the second electrode 52. A fifth impurity concentration of the first conductivity type in the fifth semiconductor member 15 is higher than the fourth impurity concentration. The fifth semiconductor member 15 is, for example, an n⁺+ region. At least a portion of the first conductive layer 31 (for example, a silicide layer) may be provided between the fifth semiconductor member 15 and the second electrode 52.

As shown in FIGS. 1 and 2, the semiconductor device 110 may further include a sixth semiconductor member 16 of the first conductivity type. The sixth semiconductor member 16 is provided between the first electrode 51 and the first semiconductor member 11 in the first direction D1. A sixth impurity concentration of the first conductivity type in the sixth semiconductor member 16 is lower than the first impurity concentration. The sixth semiconductor member 16 is, for example, an n region. The sixth semiconductor member 16 is, for example, a drift layer.

The semiconductor device 110 may further include a seventh semiconductor member 17 of the first conductivity type. The seventh semiconductor member 17 is provided between the first electrode 51 and the sixth semiconductor member 16 in the first direction D1. A seventh impurity concentration of the first conductivity type in the seventh semiconductor member 17 is higher than the first impurity concentration. The seventh semiconductor member 17 is, for example, an n⁺ region.

FIG. 3A is a cross-sectional view taken along the X-Y plane including the fourth semiconductor member 14. FIG. 3B is a cross-sectional view taken along the X-Y plane including the fifth semiconductor member 15. FIG. 3C is a cross-sectional view taken along the X-Y plane including the third semiconductor region 12c. FIG. 3D is a cross-sectional view taken along the X-Y plane including the fifth partial region 11e.

As shown in FIGS. 3C and 3D, A direction from a position of the fifth partial region 11e in the third direction D3 to a position of the fourth partial region 11d in the third direction D3 is along the second direction D2 (see FIG. 1). As shown in FIGS. 3C and 3D, for example, the position of the fifth partial region 11e in the third direction D3 coincides with the position of the fourth partial region 11d in the third direction D3.

As shown in FIG. 1, the first semiconductor member 11 may further include a sixth partial region 11f, a seventh partial region 11g, and an eighth partial region 11h. The sixth partial region 11f is located between another portion of the first partial region 11a and the second electrode 52 in the first direction D1. The second partial region 11b is located between the sixth partial region 11f and the third partial region 11c in the second direction D2. The sixth partial region 11f functions, for example, as a layer for spreading current.

The seventh partial region 11g is located between a portion of the sixth partial region 11f and the second electrode 52 in the first direction D1. The seventh partial region 11g makes Schottky contact with the second electrode 52.

The eighth partial region 11h extends along the second direction D2. The eighth partial region 11h is connected to the sixth partial region 11f and the second partial region 11b. The eighth partial region 11h is provided, for example, between the sixth partial region 11f and the second partial region 11b.

The second semiconductor member 12 further includes a sixth semiconductor region 12f, a seventh semiconductor region 12g, an eighth semiconductor region 12h, a ninth semiconductor region 12i, and a tenth semiconductor region 12j. The sixth semiconductor region 12f and the seventh semiconductor region 12g are located between another portion of the first partial region 11a and the second electrode 52 in the first direction D1.

The sixth semiconductor region 12f and the seventh semiconductor region 12g are located between the sixth partial region 11f and the second partial region 11b in the second direction D2. A direction from the sixth semiconductor region 12f to the seventh semiconductor region 12g is along the third direction D3.

The eighth partial region 11h is located between the sixth semiconductor region 12f and the seventh semiconductor region 12g in the third direction D3.

The eighth semiconductor region 12h is located between the sixth semiconductor region 12f and the second electrode 52 in the first direction D1. The ninth semiconductor region 12i is located between the seventh semiconductor region 12g and the second electrode 52 in the first direction D1. The tenth semiconductor region 12j is located between the eighth partial region 11h and the second electrode 52 in the first direction D1.

For example, the sixth semiconductor region 12f and the seventh semiconductor region 12g are separated by the eighth partial region 11h. When a reverse voltage is applied, a portion of the current flowing through the seventh partial region 11g can flow into the second partial region 11b through the eighth partial region 11h. Thereby, deterioration of the semiconductor device due to hole injection when a reverse voltage is applied can be suppressed. According to the embodiment, reverse conduction characteristics can be improved.

As shown in FIG. 3D, in the example of the semiconductor device 110, a direction from the eighth partial region 11h to the fifth partial region 11e is along the second direction D2.

In the example, a direction from the seventh partial region 11g to the fourth partial region 11d is along the second direction D2. A direction from a position of the seventh partial region 11g in the third direction D3 to a position of the eighth partial region 11h in the third direction D3 is along a direction from a position of the fifth partial region 11e in the third direction D3 to a position of the fourth partial region 11d in the third direction D3.

As shown in FIG. 1, a portion 13c of the third semiconductor member 13 is located between the eighth semiconductor region 12 h and the second electrode 52. The portion 13c of the third semiconductor member 13 is electrically connected to the second electrode 52. A portion 13d of the third semiconductor member 13 is located between the ninth semiconductor region 12i and the second electrode 52. The portion 13d of the third semiconductor member 13 is electrically connected to the second electrode 52.

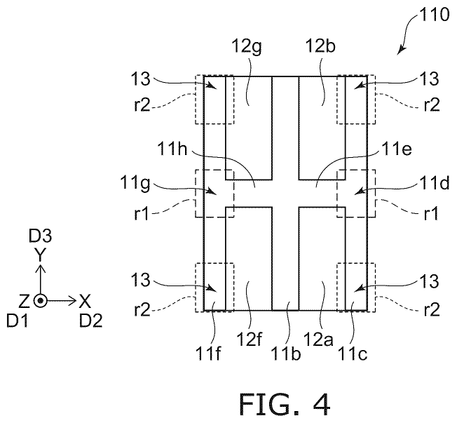

FIG. 4 is a schematic plan view illustrating the semiconductor device according to the first embodiment.

As shown in FIG. 4, the semiconductor device 110 includes a first region r1 and a second region r2. The first region r1 is, for example, a region where the fourth partial region 11d or the seventh partial region 11g is provided. The first region r1 is, for example, a region where an SBD is provided. The second region r2 is, for example, a region where the third semiconductor member 13 is provided. The second region r2 is, for example, a region where an ohmic junction is provided. The second region r2 may include, for example, a region where the fourth semiconductor member 14 is provided. The second region r2 may include, for example, a region where the fifth semiconductor member 15 is provided.

In the semiconductor device 110, a direction from a position of the fifth partial region 11e in the third direction D3 to a position of the first region r1 in the third direction D3 is along the second direction D2. A position of the fifth partial region 11e in the third direction D3 coincides with a position of the first region r1 in the third direction D3.

### Second Embodiment

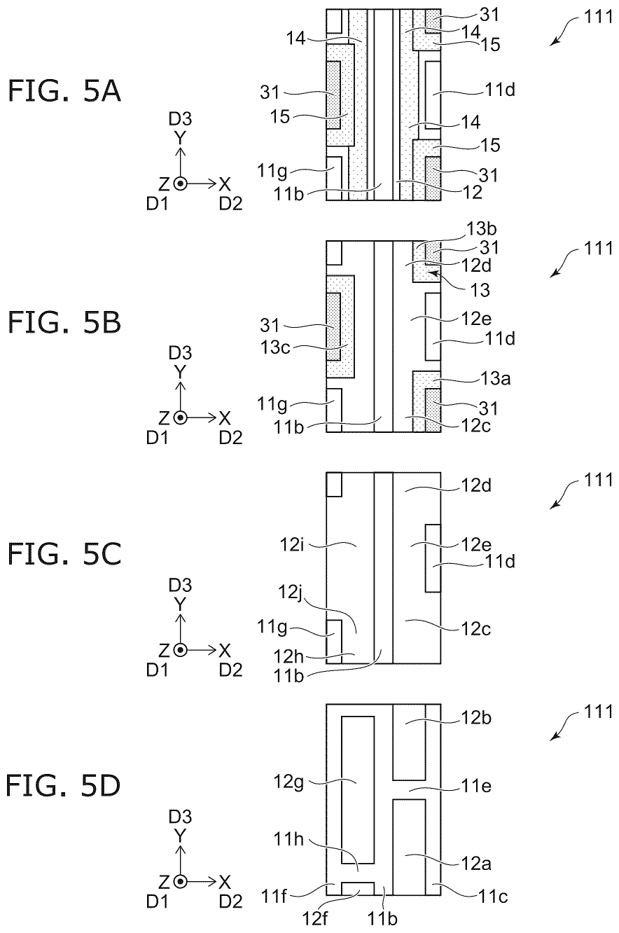

FIGS. 5A to 5D are schematic cross-sectional views illustrating a semiconductor device according to a second embodiment.

As shown in FIGS. 5C and 5D, in a semiconductor device 111 according to the embodiment, the relative positional relationship between the eighth partial region 11h and the fifth partial region 11e is different from the relationship in the semiconductor device 1110. The configuration of the semiconductor device 111 except for this may be the same as the configuration of the semiconductor device 110.

In the semiconductor device 111, a direction from the eighth partial region 11h to the fifth partial region 11e crosses the second direction D2. The eighth partial region 11h is provided at a shifted position with respect to the fifth partial region 11e.

In the semiconductor device 111 as well, the reverse conduction characteristics can be improved. In the semiconductor device 111, for example, the structure has good symmetry. Thereby, for example, current diffusion to the drift layer tends to be uniform. For example, the on-resistance when turned on in the forward direction is low. For example, the short circuit resistance is good. For example, the resistance during reverse conduction is low.

### Third Embodiment

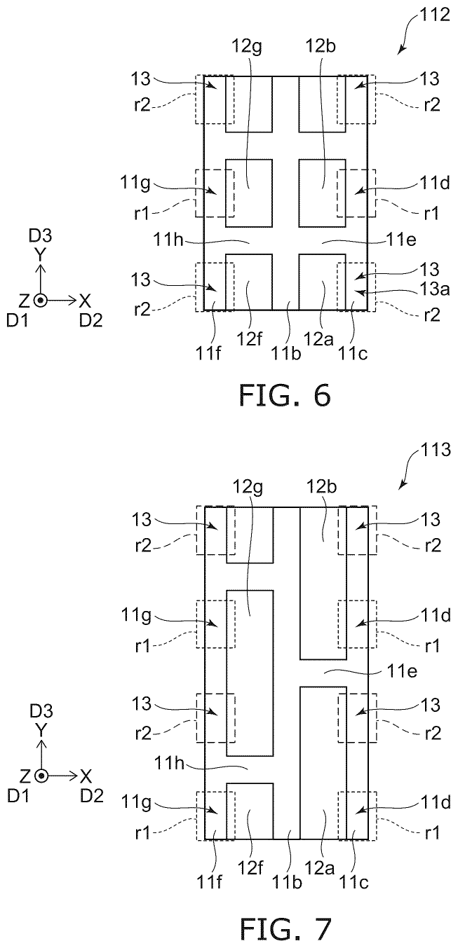

FIG. 6 is a schematic cross-sectional view illustrating a semiconductor device according to a third embodiment.

As shown in FIG. 6, in a semiconductor device 112 according to the embodiment, the position of the fifth partial region 11e is shifted with respect to the first region r1. The configuration of the semiconductor device 112 except for this may be the same as the configuration of the semiconductor device 110.

In the semiconductor device 112, the direction from the position of the fifth partial region 11e in the third direction D3 to the position of the fourth partial region 11d in the third direction D3 crosses the second direction D2. For example, the position of the fifth partial region 11e in the third direction D3 is between the position of the portion 13a of the third semiconductor member 13 in the third direction D3 and the position of the fourth partial region 11d in the third direction D3.

The reverse conduction characteristics can also be improved in the semiconductor device 112. In the semiconductor device 112, for example, a current (SBD current) passing through the fourth partial region 11d flows through a plurality of paths to the second partial region 11b. For example, in the second partial region 11b, the effect of suppressing p-n diode operation is improved.

In the semiconductor device 112, the direction from the eighth partial region 11h to the fifth partial region 11e is along the second direction D2. The direction from the position of the seventh partial region 11g in the third direction D3 to the position of the eighth partial region 11h in the third direction D3 crosses the second direction D2. The direction from the position of the fifth partial region 11e in the third direction D3 to the position of the fourth partial region 11d in the third direction D3 crosses the second direction D2.

### Fourth Embodiment

FIG. 7 is a schematic cross-sectional view illustrating a semiconductor device according to a fourth embodiment.

As shown in FIG. 7, in a semiconductor device 113 according to the embodiment, the position of the eighth partial region 11h in the third direction D3 is shifted with respect to the position of the fifth partial region 11e in the third direction D3. The configuration of the semiconductor device 113 except for this may be the same as the configuration of the semiconductor device 110.

In the semiconductor device 113, the direction from the eighth partial region 11h to the fifth partial region 11e crosses the second direction D2. The direction from the position of the seventh partial region 11g in the third direction D3 to the position of the eighth partial region 11h in the third direction D3 crosses the second direction D2. The direction from the position of the fifth partial region 11e in the third direction D3 to the position of the fourth partial region 11d in the third direction D3 crosses the second direction D2.

In the semiconductor device 113 as well, the reverse conduction characteristics can be improved. In the semiconductor device 113, conductivity modulation of the p-n diode is likely to occur, for example, when a large current of reverse conduction inrushes. As a result, voltage drop due to conduction is suppressed, and surge current resistance is ensured. For example, if the operation of the p-n diode is excessively suppressed by the SBD current, surge resistance may deteriorate. In the semiconductor device 113, the SBD effect is appropriately adjusted, and well-balanced overall characteristics can be obtained.

In the embodiment, for example, the first semiconductor member 11, the second semiconductor member 12, the third semiconductor member 13, and the fourth semiconductor member 14 contain SiC. The first semiconductor member 11, the second semiconductor member 12, the third semiconductor member 13, and the fourth semiconductor member 14 may include at least one selected from the group consisting of 4H—SiC, 6H—SiC, and 3C—SiC. These semiconductor regions contain crystals. These semiconductor members may include silicon. These semiconductor members may include a compound semiconductor containing Ga.

For example, the first conductivity type impurity includes at least one selected from the group consisting of N, P, and As. For example, the second conductivity type impurity includes at least one selected from the group consisting of B, Al, and Ga.

In one example, the concentration of the first conductivity type impurity in the first semiconductor member 11 is, for example, not less than 1×10¹⁶ cm⁻³ and not more than 1×10¹⁸ cm⁻³. In one example, the concentration of the second conductivity type impurity in the second semiconductor member 12 is, for example, not less than 1×10¹⁷ cm⁻³ and not more than 1×10²⁰ cm⁻³. In one example, the concentration of the second conductivity type impurity in the third semiconductor member 13 is, for example, not less than 1×10¹⁹ cm⁻³ and not more than 1×10²¹ cm⁻³. In one example, the concentration of the first conductivity type impurity in the fourth semiconductor member 14 is, for example, not less than 1×10¹⁹ cm⁻³ and not more than 1×10²¹ cm⁻³. In one example, the concentration of the first conductivity type impurity in the fifth semiconductor member 15 is, for example, not less than 1×10¹⁹ cm⁻³ and not more than 1×10²¹ cm⁻³. In one example, the concentration of the first conductivity type impurity in the sixth semiconductor member 16 is, for example, not less than 1×10¹⁴ cm⁻³ and not more than 1×10¹⁷ cm⁻³. In one example, the concentration of the first conductivity type impurity in the seventh semiconductor member 17 is, for example, not less than 1×10¹⁵ cm⁻³ and not more than 1× 10¹⁸ cm⁻³. The above impurity concentration may correspond to the carrier concentration, for example.

In embodiments, information regarding length and thickness is obtained by electron microscopy or the like. Information regarding the composition of the material can be obtained by SIMS (Secondary Ion Mass Spectrometry), EDX (Energy dispersive X-ray spectroscopy), or the like.

The embodiments may include the following Technical proposals:

### Technical Proposal 1

A semiconductor device, comprising:
a first electrode;
a second electrode;
a first semiconductor member of a first conductivity type, the first semiconductor member being provided between the first electrode and the second electrode, the first semiconductor member including a first partial region, a second partial region, a third partial region, a fourth partial region, and a fifth partial region, the second partial region and the third partial region being located between a portion of the first partial region and the second electrode in a first direction from the first electrode to the second electrode, a second direction from the second partial region to the third partial region crossing the first direction, the fourth partial region being provided between a portion of the third partial region and the second electrode in the first direction, the fourth partial region being in Schottky contact with the second electrode, the fifth partial region extending along the second direction, the fifth partial region being connected to the second partial region and the third partial region;
a second semiconductor member of a second conductivity type, the second semiconductor member including a first semiconductor region, a second semiconductor region, a third semiconductor region, a fourth semiconductor region, and a fifth semiconductor region, the first semiconductor region and the second semiconductor region being provided between another portion of the first partial region and the second electrode in the first direction, the first semiconductor region and the second semiconductor region being provided between the second partial region and the third partial region in the second direction, a third direction from the first semiconductor region to the second semiconductor region crossing a plane including the first direction and the second direction, the fifth partial region being provided between the first semiconductor region and the second semiconductor region in the third direction, the third semiconductor region being provided between the first semiconductor region and the second electrode in the first direction, the fourth semiconductor region being provided between the second semiconductor region and the second electrode in the first direction, the fifth semiconductor region being provided between the fifth partial region and the second electrode in the first direction;
a third semiconductor member of the second conductivity type, a portion of the third semiconductor member being provided between the third semiconductor region and the second electrode, and being electrically connected to the second electrode, a third impurity concentration of the second conductivity type in the third semiconductor member being higher than a second impurity concentration of the second conductivity type in the second semiconductor member;
a fourth semiconductor member of the first conductivity type, a portion of the fourth semiconductor member being provided between the third semiconductor region and the second electrode, and being electrically connected to the second electrode, a fourth impurity concentration of the first conductivity type in the fourth semiconductor member being higher than a first impurity concentration of the first conductivity type in the first semiconductor member;
a third electrode, a direction from the second partial region to at least a portion of the third electrode being along the first direction; and
a first insulating member including a first insulating region, the first insulating region being provided between the second partial region and the at least the portion of the third electrode.

### Technical Proposal 2

The semiconductor device according to Technical proposal 1, wherein
the portion of the third semiconductor member is in ohmic contact with the second electrode.

### Technical Proposal 3

The semiconductor device according to Technical proposal 1 or 2, wherein
another portion of the third semiconductor member is provided between the fourth semiconductor region and the second electrode and is in ohmic contact with the second electrode.

### Technical Proposal 4

The semiconductor device according to any one of Technical proposals 1-3, further comprising:
a fifth semiconductor member of the first conductivity type,
a portion of the fifth semiconductor member being provided between the portion of the third semiconductor member and the second electrode, and being electrically connected to the second electrode, and a fifth impurity concentration of the first conductivity type in the fifth semiconductor member being higher than the fourth impurity concentration.

### Technical Proposal 5

The semiconductor device according to any one of Technical proposals 1-4, wherein
a direction from a position of the fifth partial region in the third direction to a position of the fourth partial region in the third direction is along the second direction.

### Technical Proposal 6

The semiconductor device according to any one of Technical proposals 1-4, wherein
a position of the fifth partial region in the third direction coincide with a position of the fourth partial region in the third direction.

### Technical Proposal 7

The semiconductor device according to any one of Technical proposals 1-4, wherein
a direction from a position of the fifth partial region in the third direction to a position of the fourth partial region in the third direction crosses the second direction.

### Technical Proposal 8

The semiconductor device according to any one of Technical proposals 1-4, wherein
a position of the fifth partial region in the third direction is between a position of the portion of the third semiconductor member in the third direction and a position of the fourth partial region in the third direction.

### Technical Proposal 9

The semiconductor device according to any one of Technical proposals 1-4, wherein
the first semiconductor member further includes a sixth partial region, a seventh partial region, and an eighth partial region,
the sixth partial region is provided between another portion of the first partial region and the second electrode in the first direction,
the second partial region is provided between the sixth partial region and the third partial region in the second direction,
the seventh partial region is provided between a portion of the sixth partial region and the second electrode in the first direction,
the seventh partial region is in Schottky contact with the second electrode,
the eighth partial region extends along the second direction, the eighth partial region is connected to the sixth partial region and the second partial region,
the second semiconductor member further includes a sixth semiconductor region, a seventh semiconductor region, an eighth semiconductor region, a ninth semiconductor region, and a tenth semiconductor region,
the sixth semiconductor region and the seventh semiconductor region are provided between another portion of the first partial region and the second electrode in the first direction,
the sixth semiconductor region and the seventh semiconductor region are provided between the sixth partial region and the second partial region in the second direction,
a direction from the sixth semiconductor region to the seventh semiconductor region is along the third direction,
the eighth partial region is provided between the sixth semiconductor region and the seventh semiconductor region in the third direction,
the eighth semiconductor region is provided between the sixth semiconductor region and the second electrode in the first direction,
the ninth semiconductor region is provided between the seventh semiconductor region and the second electrode in the first direction, and
the tenth semiconductor region is provided between the eighth partial region and the second electrode in the first direction.

### Technical Proposal 10

The semiconductor device according to Technical proposal 9, wherein
a direction from the eighth partial region to the fifth partial region is along the second direction.

### Technical Proposal 11

The semiconductor device according to Technical proposal 9, wherein
a direction from the seventh partial region to the fourth partial region is along the second direction, and a direction from a position of the seventh partial region in the third direction to a position of the eighth partial region in the third direction is along a direction from a position of the fifth partial region in the third direction to a position of the fourth partial region in the third direction.

### Technical Proposal 12

The semiconductor device according to Technical proposal 9, wherein
a direction from the eighth partial region to the fifth partial region crosses the second direction.

### Technical Proposal 13

The semiconductor device according to Technical proposal 9, wherein
a direction from the eighth partial region to the fifth partial region is along the second direction,
a direction from a position of the seventh partial region in the third direction to a position of the eighth partial region in the third direction crosses the second direction, and
a direction from a position of the fifth partial region in the third direction to a position of the fourth partial region in the third direction crosses the second direction.

### Technical Proposal 14

The semiconductor device according to Technical proposal 9, wherein
a direction from the eighth partial region to the fifth partial region crosses the second direction,
a direction from a position of the seventh partial region in the third direction to a position of the eighth partial region in the third direction crosses the second direction, and
a direction from a position of the fifth partial region in the third direction to a position of the fourth partial region in the third direction crosses the second direction.

### Technical Proposal 15

The semiconductor device according to any one of Technical proposals 1-14, further comprising:
a sixth semiconductor member of the first conductivity type,
the sixth semiconductor member being provided between the first electrode and the first semiconductor member in the first direction, and
a sixth impurity concentration of the first conductivity type in the sixth semiconductor member being lower than the first impurity concentration.

### Technical Proposal 16

The semiconductor device according to Technical proposal 15, further comprising:
a seventh semiconductor member of the first conductivity type,
the seventh semiconductor member being provided between the first electrode and the sixth semiconductor member in the first direction, and
a seventh impurity concentration of the first conductivity type in the seventh semiconductor member being higher than the first impurity concentration.

### Technical Proposal 17

The semiconductor device according to any one of Technical proposals 1-16, further comprising:
a first conductive layer containing silicide,
at least a portion of the first conductive layer being provided between the third semiconductor member and the second electrode.

### Technical Proposal 18

The semiconductor device according to any one of Technical proposals 1-17, further comprising:
the second electrode including a facing region facing the fourth partial region, and
the facing region including at least one selected from the group consisting of Ni, Ti, V, and Mo.

### Technical Proposal 19

The semiconductor device according to any one of Technical proposals 1-18, wherein
the first semiconductor member, the second semiconductor member, the third semiconductor member, and the fourth semiconductor member include SiC.

### Technical Proposal 20

The semiconductor device according to any one of Technical proposals 1-19, wherein
a portion of the first insulating member is provided between the fourth semiconductor member and the third electrode.

According to the embodiment, a semiconductor device with improved characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a first semiconductor member of a first conductivity type, the first semiconductor member being provided between the first electrode and the second electrode, the first semiconductor member including a first partial region, a second partial region, a third partial region, a fourth partial region, and a fifth partial region, the second partial region and the third partial region being located between a portion of the first partial region and the second electrode in a first direction from the first electrode to the second electrode, a second direction from the second partial region to the third partial region crossing the first direction, the fourth partial region being provided between a portion of the third partial region and the second electrode in the first direction, the fourth partial region being in Schottky contact with the second electrode, the fifth partial region extending along the second direction, the fifth partial region being connected to the second partial region and the third partial region;
a second semiconductor member of a second conductivity type, the second semiconductor member including a first semiconductor region, a second semiconductor region, a third semiconductor region, a fourth semiconductor region, and a fifth semiconductor region, the first semiconductor region and the second semiconductor region being provided between another portion of the first partial region and the second electrode in the first direction, the first semiconductor region and the second semiconductor region being provided between the second partial region and the third partial region in the second direction, a third direction from the first semiconductor region to the second semiconductor region crossing a plane including the first direction and the second direction, the fifth partial region being provided between the first semiconductor region and the second semiconductor region in the third direction, the third semiconductor region being provided between the first semiconductor region and the second electrode in the first direction, the fourth semiconductor region being provided between the second semiconductor region and the second electrode in the first direction, the fifth semiconductor region being provided between the fifth partial region and the second electrode in the first direction;
a third semiconductor member of the second conductivity type, a portion of the third semiconductor member being provided between the third semiconductor region and the second electrode, and being electrically connected to the second electrode, a third impurity concentration of the second conductivity type in the third semiconductor member being higher than a second impurity concentration of the second conductivity type in the second semiconductor member;
a fourth semiconductor member of the first conductivity type, a portion of the fourth semiconductor member being provided between the third semiconductor region and the second electrode, and being electrically connected to the second electrode, a fourth impurity concentration of the first conductivity type in the fourth semiconductor member being higher than a first impurity concentration of the first conductivity type in the first semiconductor member;
a third electrode, a direction from the second partial region to at least a portion of the third electrode being along the first direction; and
a first insulating member including a first insulating region, the first insulating region being provided between the second partial region and the at least the portion of the third electrode.

2. The device according to claim 1, wherein
the portion of the third semiconductor member is in ohmic contact with the second electrode.

3. The device according to claim 1, wherein
another portion of the third semiconductor member is provided between the fourth semiconductor region and the second electrode and is in ohmic contact with the second electrode.

4. The device according to claim 1, further comprising:
a fifth semiconductor member of the first conductivity type,
a portion of the fifth semiconductor member being provided between the portion of the third semiconductor member and the second electrode, and being electrically connected to the second electrode, and a fifth impurity concentration of the first conductivity type in the fifth semiconductor member being higher than the fourth impurity concentration.

5. The device according to claim 1, wherein
a direction from a position of the fifth partial region in the third direction to a position of the fourth partial region in the third direction is along the second direction.

6. The device according to claim 1, wherein
a position of the fifth partial region in the third direction coincide with a position of the fourth partial region in the third direction.

7. The device according to claim 1, wherein
a direction from a position of the fifth partial region in the third direction to a position of the fourth partial region in the third direction crosses the second direction.

8. The device according to claim 1, wherein
a position of the fifth partial region in the third direction is between a position of the portion of the third semiconductor member in the third direction and a position of the fourth partial region in the third direction.

9. The device according to claim 1, wherein
the first semiconductor member further includes a sixth partial region, a seventh partial region, and an eighth partial region,
the sixth partial region is provided between another portion of the first partial region and the second electrode in the first direction,
the second partial region is provided between the sixth partial region and the third partial region in the second direction,
the seventh partial region is provided between a portion of the sixth partial region and the second electrode in the first direction,
the seventh partial region is in Schottky contact with the second electrode,
the eighth partial region extends along the second direction, the eighth partial region is connected to the sixth partial region and the second partial region,
the second semiconductor member further includes a sixth semiconductor region, a seventh semiconductor region, an eighth semiconductor region, a ninth semiconductor region, and a tenth semiconductor region,
the sixth semiconductor region and the seventh semiconductor region are provided between another portion of the first partial region and the second electrode in the first direction,
the sixth semiconductor region and the seventh semiconductor region are provided between the sixth partial region and the second partial region in the second direction,
a direction from the sixth semiconductor region to the seventh semiconductor region is along the third direction,
the eighth partial region is provided between the sixth semiconductor region and the seventh semiconductor region in the third direction,
the eighth semiconductor region is provided between the sixth semiconductor region and the second electrode in the first direction,
the ninth semiconductor region is provided between the seventh semiconductor region and the second electrode in the first direction, and
the tenth semiconductor region is provided between the eighth partial region and the second electrode in the first direction.

10. The device according to claim 9, wherein
a direction from the eighth partial region to the fifth partial region is along the second direction.

11. The device according to claim 9, wherein
a direction from the seventh partial region to the fourth partial region is along the second direction, and
a direction from a position of the seventh partial region in the third direction to a position of the eighth partial region in the third direction is along a direction from a position of the fifth partial region in the third direction to a position of the fourth partial region in the third direction.

12. The device according to claim 9, wherein
a direction from the eighth partial region to the fifth partial region crosses the second direction.

13. The device according to claim 9, wherein
a direction from the eighth partial region to the fifth partial region is along the second direction,
a direction from a position of the seventh partial region in the third direction to a position of the eighth partial region in the third direction crosses the second direction, and
a direction from a position of the fifth partial region in the third direction to a position of the fourth partial region in the third direction crosses the second direction.

14. The device according to claim 9, wherein
a direction from the eighth partial region to the fifth partial region crosses the second direction,
a direction from a position of the seventh partial region in the third direction to a position of the eighth partial region in the third direction crosses the second direction, and
a direction from a position of the fifth partial region in the third direction to a position of the fourth partial region in the third direction crosses the second direction.

15. The device according to claim 1, further comprising:
a sixth semiconductor member of the first conductivity type,
the sixth semiconductor member being provided between the first electrode and the first semiconductor member in the first direction, and
a sixth impurity concentration of the first conductivity type in the sixth semiconductor member being lower than the first impurity concentration.

16. The device according to claim 15, further comprising:
a seventh semiconductor member of the first conductivity type,
the seventh semiconductor member being provided between the first electrode and the sixth semiconductor member in the first direction, and
a seventh impurity concentration of the first conductivity type in the seventh semiconductor member being higher than the first impurity concentration.

17. The device according to claim 1, further comprising:
a first conductive layer containing silicide,
at least a portion of the first conductive layer being provided between the third semiconductor member and the second electrode.

18. The device according to claim 1, further comprising:
the second electrode including a facing region facing the fourth partial region, and
the facing region including at least one selected from the group consisting of Ni, Ti, V, and Mo.

19. The device according to claim 1, wherein
the first semiconductor member, the second semiconductor member, the third semiconductor member, and the fourth semiconductor member include SiC.

20. The device according to claim 1, wherein
a portion of the first insulating member is provided between the fourth semiconductor member and the third electrode.
